(19) United States
(12) Patent Application Publication
(10) Pub. No.: US 2009/0000651 A1
(43) Pub. Date: Jan. 1, 2009

(54) Nanoporous Materials for Use in the Conversion of Mechanical Energy and/or Thermal Energy Into Electrical Energy

(75) Inventor: Yu Qiao, San Deigo, CA (US)

Correspondence Address: ROETZEL AND ANDRESS, 222 SOUTH MAIN STREET, AKRON, OH, 44308, US

(73) Assignee: THE UNIVERSITY OF AKRON, Akron, OH (US)

(21) Appl. No.: 11/995,382

(22) PCT Filed: Aug. 18, 2006
(86) PCT No.: PCT/US2006/032472

§ 371 Date: Jun. 13, 2008

Related U.S. Application Data
(60) Provisional application No. 60/709,851, filed on Aug. 19, 2005.

(51) Int. Cl. H01L 35/30; H02N 11/00

(52) U.S. Cl. 136/205; 310/300

(57) ABSTRACT

The present invention generally relates to a method for using nanoporous materials to convert mechanical motion and/or heat into electrical energy. In one embodiment, the present invention relates to the use of a nanopore confinement effect that results from a fluid infiltrating a porous material as a means to generating electrical energy. In another embodiment, the present invention relates to the use of a nanopore confinement effect that results from a continuous solid phase infiltrating a porous material as a means to generate electrical energy. In still another embodiment, the present invention relates to the use of a thermoelectric effect that results from a fluid infiltrating a porous material as a means to generate electrical energy. In yet another embodiment, the present invention relates to the use of a thermoelectric effect that results from a continuous solid phase infiltrating a porous material as a means to generate electrical energy. In yet another embodiment, the present invention relates to applying the foregoing mechanoelectric effect or thermoelectric effect to high surface area and/or small-structured solids as a means of enhancing and/or supplementing otherwise inefficient and/or insufficient electrical energy generation.

### FIELD OF THE INVENTION

The present invention generally relates to a method for using nanoporous materials to convert mechanical motion and/or heat into electrical energy. In one embodiment, the present invention relates to the use of a nanopore confinement effect that results from a fluid infiltrating a porous material as a means to generating electrical energy. In another embodiment, the present invention relates to the use of a nanopore confinement effect that results from a continuous solid phase infiltrating a porous material as a means to generate electrical energy. In still another embodiment, the present invention relates to the use of a thermoelectric effect that results from a fluid infiltrating a porous material as a means to generate electrical energy. In yet another embodiment, the present invention relates to the use of a thermoelectric effect that results from a continuous solid phase infiltrating a porous material as a means to generate electrical energy. In yet another embodiment, the present invention relates to applying the foregoing mechanoelectric effect or thermoelectric effect to high surface area and/or small-structured solids as a means of enhancing and/or supplementing otherwise inefficient and/or insufficient electrical energy generation.

### BACKGROUND OF THE INVENTION

One type of conventional ion separation generators include water drop electrostatic generators. As drops of an ionized aqueous liquid separate from a body of the liquid, they carry excess ions. Therefore, charge separation can be achieved. According to this method, liquid ionization is achieved using electrodes. In general, as an electric field is applied across the liquid phase, the cations and anions in the liquid are attracted to the oppositely charged electrodes, and thus the ion distribution becomes heterogeneous. Alternatively, charge separation can be achieved in ionic liquids through an electrostatic effect. In this case, as a liquid flows over a solid surface or through a nozzle, ion mobility at the solid-liquid interface double layer is lower than that of the bulk liquid phase. Thus, the liquid flow carries excess charges. In either case, mechanical work is done by gravitational force or by external loading so as to overcome the electrical forces associated with charge separation. Accordingly, mechanical energy is converted into electrical energy. Thus, the device is mechanoelectrical. Systems such as these suffer from a number of problems that render them impractical. Among these problems is their very low power generation efficiency and rate.

The electrostatic effect can be amplified by the large surface area of a nanoporous material. For instance, if the electrostatic charge separation at a solid-liquid interface double layer occurs in a nanochannel or a nanopore, similar mechanical-to-electrical energy conversion can be observed. Due to the large surface area, the overall energy conversion efficiency can be improved. However, charge separation in this system is still caused by the difference in ion mobility in the interfacial double layer relative to a bulk electrolyte. Moreover, to form a double layer, the size of the nanochannel and/or nanopore must be larger than, or at least comparable to, the double layer thickness. Thus this technique cannot be extended to microporous materials of the smallest nanopores and the largest specific surface areas.

In view of the foregoing, there is a need in the art for a device and method for efficiently generating electrical energy using mechanoelectrical and/or thermoelectrical principles.

### SUMMARY OF THE INVENTION

The present invention generally relates to a method for using nanoporous materials to convert mechanical motion and/or heat into electrical energy. In one embodiment, the present invention relates to the use of a nanopore confinement effect that results from a fluid infiltrating a porous material as a means to generating electrical energy. In another embodiment, the present invention relates to the use of a nanopore confinement effect that results from a continuous solid phase infiltrating a porous material as a means to generate electrical energy. In still another embodiment, the present invention relates to the use of a thermoelectric effect that results from a fluid infiltrating a porous material as a means to generate electrical energy. In yet another embodiment, the present invention relates to the use of a thermoelectric effect that results from a continuous solid phase infiltrating a porous material as a means to generate electrical energy. In yet another embodiment, the present invention relates to applying the foregoing mechanoelectric effect or thermoelectric effect to high surface area and/or small-structured solids as a means of enhancing and/or supplementing otherwise inefficient and/or insufficient electrical energy generation.

In one embodiment, the present invention relates to a mechanoelectric power generating device comprising: a nanoporous material disposed within a containment means, wherein the nanoporous material is capable of separating ions according to size; an electrolyte containing anions and cations disposed within the containment means, wherein the electrolyte is made up of anions and cations that differ in size so that the smaller ion is capable of permeating the nanoporous material, and wherein the larger ions are substantially excluded from the nanoporous material, and wherein the electrolyte is capable of being contained within the containment means; a loading means located and/or disposed within the containment means, wherein the loading means is capable of imparting a mechanical load upon the contents of the containment means, the load being sufficient to cause at least a portion of the electrolyte to at least partially infiltrate the nanoporous material; and at least one contact in electrical communication with the containment means, the electrolyte and/or the nanoporous material, wherein the contact is capable of harvesting any excess electrical charge.

In another embodiment, the present invention relates to a thermoelectric power generating devices comprising: a conductive means that is capable of conducting charge to and from a nanoporous material, wherein the conductive means is disposed in a containment means; a nanoporous material disposed within the containment means, wherein the nanoporous material is capable of separating charge and/or containing excess charge, wherein the nanoporous material and the conductive means are in thermal and electrical communication with the containment means; a temperature control means designed to permit control of the temperature of the containment means, the conductive means, and the nanoporous material; and a means for harvesting excess charge from the conductive means and/or containment means.

### BRIEF DESCRIPTION OF THE DRAWINGS

FIG. 1(a) a schematic diagram of a mechanoelectrical device formed in accordance with one embodiment of the present invention;

FIG. 1(b) is a graph illustrating the measured output voltage as a function of time for the device of FIG. 1(a);

FIG. 2(a) is a schematic diagram of a thermoelectric device formed in accordance with one embodiment of the present invention;

FIG. 2(b) is a graph illustrating the measured output voltage as a function of temperature for the device of FIG. 2(b);

FIG. 3(a) is a schematic diagram of a thermoelectric device formed in accordance with another embodiment of the present invention;

FIG. 3(b) is a graph illustrating the potential difference, at two different m values, as a function of a change in temperature (ΔT), where m is the mass of the nanoporous carbon electrode;

FIG. 4 is a schematic diagram of a mechanoelectric device formed in accordance with another embodiment of the present invention;

FIG. 5 is a schematic diagram of a mechanoelectric device formed in accordance with still another embodiment of the present invention;

FIG. 6 is a schematic diagram of a thermoelectric device formed in accordance with still another embodiment of the present invention, where the thermoelectric device is based on a nanopore confinement effect; and

FIG. 7 is a schematic diagram illustrating a double layer effect in a system in accordance with the present invention, where such system comprises a generalized electrode surface in contact with an electrolyte.

### DETAILED DESCRIPTION OF THE INVENTION

The present invention generally relates to a method for using nanoporous materials to convert mechanical motion and/or heat into electrical energy. In one embodiment, the present invention relates to the use of a nanopore confinement effect that results from a fluid infiltrating a porous material as a means to generating electrical energy. In another embodiment, the present invention relates to the use of a nanopore confinement effect that results from a continuous solid phase infiltrating a porous material as a means to generate electrical energy. In still another embodiment, the present invention relates to the use of a thermoelectric effect that results from a fluid infiltrating a porous material as a means to generate electrical energy. In yet another embodiment, the present invention relates to the use of a thermoelectric effect that results from a continuous solid phase infiltrating a porous material as a means to generate electrical energy. In yet another embodiment, the present invention relates to applying the foregoing mechanoelectric effect or thermoelectric effect to high surface area and/or small-structured solids as a means of enhancing and/or supplementing otherwise inefficient and/or insufficient electrical energy generation.

Nanoporous materials, as used herein, includes materials having average pore sizes or microchannel/microtube sizes from about 0.5 nm to about 1,000 nm, and can be either electrically conductive or electrically non-conductive. Nanoporous materials within the scope of the present invention include microporous materials with pore sizes smaller than about 2 nm, mesoporous materials with pore sizes larger than about 2 nm but smaller than about 50 nm, macroporous materials with pore sizes larger than about 50 nm, as well as clusters or stacks of nanodots, nanoparticles, nanowires, nanorods, and nanolayers and other nano and/or micro-structured materials having high surface areas. Nanoporous materials within the scope of the present invention also include micro/nano-electromechanical systems (MNEMS) devices containing micro and/or nano-channels/tubes. The only limitation on the kinds of materials that can comprise a nanoporous material of the present invention is that appropriate material(s) must be capable of being formed into one or more of the foregoing structures.

Exemplary nanoporous materials within the scope of the present invention include, but are not limited to, nanoporous oxides, nanoporous silicon, nanoporous carbons, zeolites or zeolite-like materials such as silicalites, porous polymers, porous metals and alloys, natural clays, or any combination of two or more thereof. In another embodiment, exemplary nanoporous materials within the scope of the present invention include, but are not limited to, silica, titania, alumina, zirconia, magnesia, Nb₂O₅, SnO₂, In₂O₃, ZnO, kaolins, serpentines, smectites, glauconite, chlorites, vermiculites, attapulgite, sepiolite, allophane, imogolite, zeolites, silicalite, silicon, silicones, polypyrrole, binary compounds (e.g., sulfides and nitrides), polyurethanes, acetates, amorphous carbons, semi-crystalline carbons, crystalline carbons, carbon nanotubes, graphene layers, iron, steel, gold, silver, copper, or any suitable combination of two or more thereof. In still another embodiment, exemplary nanoporous materials within the scope of the present invention include, but are not limited to, diatoms, radiolarii, and abalone shell. Additionally, nanoporous materials within the scope of the present invention include, but are not limited to, polymers such as latex, polyolefins, and polyurethanes.

Additionally, one of ordinary skill in the art would recognize that any of the foregoing materials alone, or in combination, can be modified with one or more surface coatings as a means of altering its surface properties. To this end, one of ordinary skill in the art would readily recognize that a wide variety of functional groups are available for appropriate surface modifications. Exemplary functional groups include, but are not limited to, hydroxyls, silanes, siloxanes, organically substituted siloxanes, alcohols, phenols, amines, carboxylic acids, sulfates, sulfites, sulfides, nitrates, nitrites, nitrides, phosphates, phosphites, nitrites, isocyanides, isothiocyanides, thiols, or any suitable combination of two or more thereof.

Liquids within the scope of the present invention can be either conductive or non-conductive. Exemplary liquids within the scope of the present invention include, but are not limited to, distilled and/or de-ionized water, waters having one or more dissolved chemicals, molten metals and/or alloys, molten salts (e.g., organic molten salts and inorganic molten salts), oils, oil-based solutions, alcohols, alcohol solutions. In still another embodiment, exemplary liquids within the scope of the present invention include, but are not limited to, benzene, toluene, n-heptane and the like. Molten metals and/or within the scope of the present invention include, but are not limited to, mercury, gallium, lead, copper, iron, nickel, Monel and any combination thereof. Monel is a trademark of Inco Alloys International, of West Va., and can be purchased from any of a variety of sources including Chand Eisenmann Metallurgical, Inc.

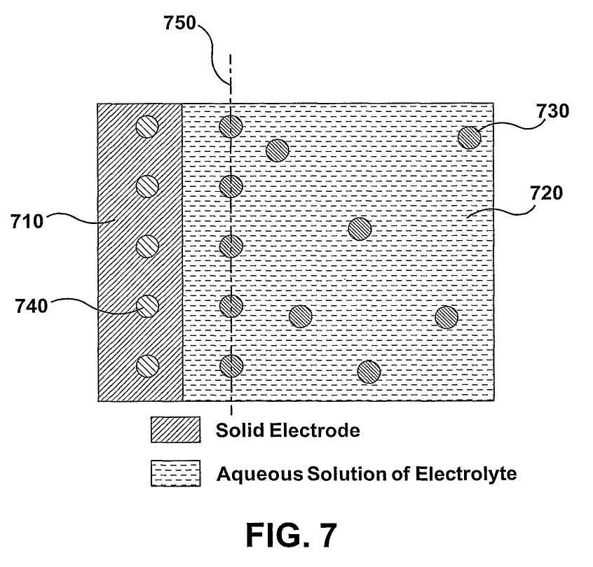

Both mechanoelectric and thermoelectric embodiments of the present invention comprise at least one solid electrode in electrical contact with a liquid electrolyte. Generally, contacting an electrode carrying excess charge with a liquid electrolyte results in the formation of a double layer, as shown in FIG. 7. For example, when the electrode 710 carries and excess charge 740, that charge aligns with corresponding opposite charges in the surrounding electrolyte solution 720. The region near the surface of the electrode where solvated ions tend to align with charges in the electrode is called the outer Helmholtz plane 750. Beyond that plane, the solvated ions 730 behave substantially independent of the electric field of the electrode.

The mechanoelectric embodiments of the present invention operate, in part, on the difference in mobility between anions and cations in a nanoporous material. More specifically, if the nanopore is large enough to accept the smaller ion but small enough to exclude the larger ion, the liquid can comprise and/or assume two differently charged regions (i.e., charge separation). The confined liquid in the nanopores has an excess of the smaller ion, and the bulk liquid outside the nanoporous material has an excess of the larger ion. Excess charge is collected using a large-surface-area electrode. Thus, a considerable portion of the mechanical work that is done in relation to liquid infiltration can be converted to electric energy.

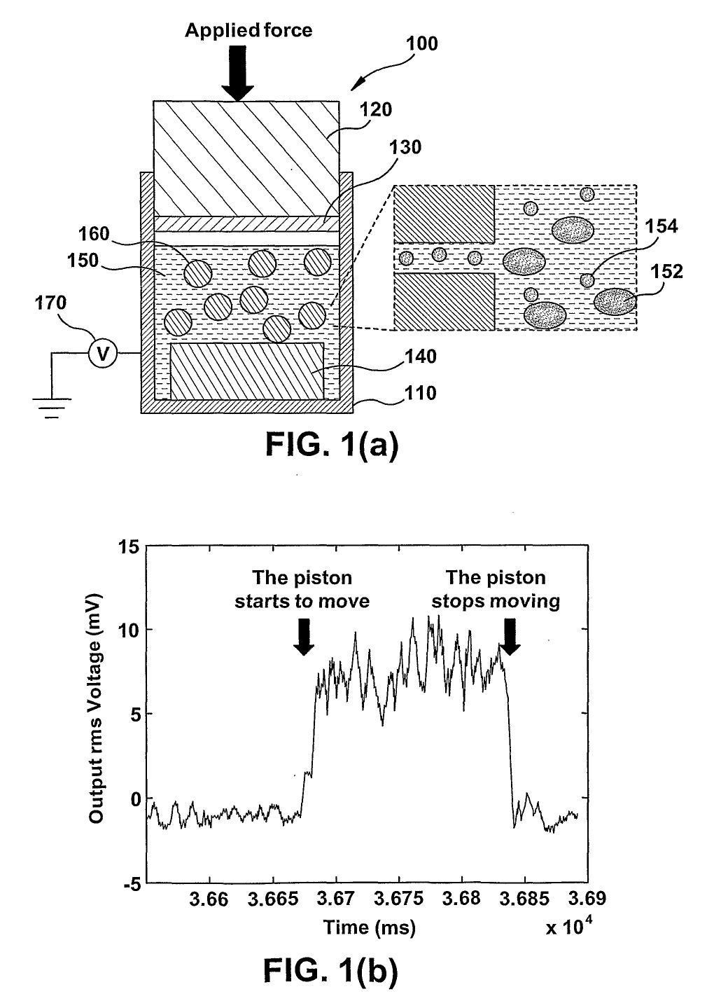

FIG. 1(a) illustrates one mechanoelectric embodiment of the present invention. As is shown in FIG. 1(a), device 100 includes a cylinder 110 (also referred to as a container) and a piston 120 fitted with an O-ring seal 130. Cylinder 110 contains an electrolyte solution 150 and a nanoporous material 160. Electrolyte solution 150 includes smaller ions 154 and larger ions 152, which differ in their mobility within and/or into the nanoporous material. Voltage changes as a function of compression, and can be measured with a voltmeter 170. A representative root-mean-square (rms) voltage curve is shown in FIG. 1(b). The y-axis shows rms output voltage and the x-axis is time. As time progresses the piston is compressed, which results in a voltage increase. Output continues as long as the piston continues to compress, and drops to zero when compression stops.

In one example, device 100 comprises about 0.5 grams of nanoporous silicalite (ZSM-5) immersed in about 4.0 grams of an aqueous solution of 27% NaCl, which is sealed in a stainless steel container with a stainless steel piston having an O-ring seal (113 PU70, O-rings Inc.). The ZSM-5 zeolite is hydrothermally synthesized with the molar ratios of 0.01 Na₂O/1.0 ethylamine/1.0 SiO₂/15 H₂O to the reactant. The Na₂O is calculated from NaOH. The ethylamine utilized is 70% in H₂O (E3754, Sigma-Aldrich). The silicon source is silica sol (LUDOX HS-30 colloidal silica, 30 weight percent, 420824, Sigma-Aldrich). The water is de-ionized water (3234-7, VWR). The reactant is then sealed in a 50 mL stainless steel autoclave and hydrothermally reacted at 180° C. for 18 hours without stirring. The stainless steel autoclave included a cylinder and a cap which are sealed tightly. The cylinder includes an approximately 4 mm thick polytetrafluoroethylene liner.

The silica sol with ethylamine template crystallizes under high temperature and pressure generated in the autoclave. The as-synthesized product is washed with cold de-ionized water, filtered with a Buchner funnel and Whatman filter paper, dried in an oven (1410, VWR) at 100° C. for one hour, and then calcined in a furnace (HTF55322A, VWR) at 550° C. for two hours with a flow of air sufficient to remove the organic template.

It should be noted, that the above embodiment of the present invention is not limited to use the of ZSM-5 zeolite for the energy generation, and that a variety of other materials can be used and/or replace the ZSM-5. Alternatively, a combination of one or more materials can be used, with such a combination including, or not including, ZSM-5. In one instance, ZSM-5 can be replaced by any nanoporous material with a suitable nanopore size. In other words, the nanopore size should be considerably larger than one type of ion (either the anion or cation) and comparable or smaller than that of the counter ion.

Similarly, it should be noted, that the above embodiment of the present invention is not limited to the electrolytes set forth in the foregoing example. Rather, the electrolytes utilized therein can include any electrolytes and/or polyelectrolytes comprised of positively charged and negatively charged ions having sizes that are different enough to be preferentially accepted/excluded by the chosen nanoporous material. Such materials include, but are not limited to, chlorides, acetate, iodates, nitrates, nitrites, hydroxides, sulfides, pyroantimonates, sulfites, sulfates, metavanadates, tungstates, phosphates, phosphate monobasic/dibasic salts, tetraborates, bromides, bromates, oxalates, chlorates, carbonates, chromates, dichromates, bicarbonates, Fe(CN)₆⁴⁻ salts, pyrophosphates (e.g., pyrophosphate tetrabasic or dibasic salts), methyltrioctylammonium salts and related polyelectrolytes, cesium salts and related polyelectrolytes, hexadecyltrimethylammonium salts and related polyelectrolytes, and tetrabutylammonium salts and related polyelectrolytes.

In some embodiments the container and the piston can be insulated with polytetrafluoroethylene tape. Some embodiments optionally include a porous Monel rod (OD: 0.3750 inch; length: 0.75 inch; micron grade: 0.5; available from Chand Eisenmann Metallurgical, Inc.) that can be placed at the bottom of the container to act as an electrode. However, any of a variety of porous metals and/or alloys can be substituted for the rod set forth above. Moreover, the shape of the electrode is not limited to the rod shape set forth above, but rather can be any convenient shape including a disk, a washer, a ribbon, a wire, spherical, ellipsoidal, or irregular.

In other embodiments the voltage of the stainless steel container can be monitored. Monitoring can be continuous, intermittent, a combination of continuous and intermittent. Furthermore, such monitoring can be carried out by any appropriate means. Such monitoring means can include, but is not limited to, a multimeter, a voltmeter, and/or a computer of any appropriate kind. In one specific example, monitoring can be accomplished with an NI 6036E DAQ board, hosted by a computer running Labview software.

In one example the average nanopore size of a silicalite is 0.53×0.56 nm, and the pore size of the Monel electrode is 500 nm. The nanopore size is much larger than the cation but somewhat comparable to the size of the anion. In this example, the dimensions of the Monel rod is 0.1×0.3 inches, and it is used to increase the contact area between the liquid phase and the electrode. The height of the container is about 1.5 inches, and the inner diameter is about 0.75 inch. The size of the sodium cation is 0.095 nm, and the size of the chloride anion is 0.18 nm. The silicalite is hydrophobic, and therefore when no external loading is applied the liquid can not enter the nanopores.

In this example, a compressive load is then applied through the piston using a type-5569 Instron machine. The rate of the crosshead is set to about 1 mm/min. As the piston is compressed into the container, the inner pressure increases. When the capillary effect of nanopores is overcome, the liquid is forced into the nanopores. Since the large anions resist entering the relatively small nanopores, cation infiltration exceeds that of anion infiltration, and as a result charge separation and/or isolation occurs. In this example, the confined liquid inside the nanopores is positively charged, and the bulk liquid outside the nanopores is negatively charged. At the interface of the electrode (the inner surface of the steel container and the pore surface of the porous Monel rod), double layers are formed and countercharges are induced in the solid, leading to a net output voltage between the electrode and the ground.

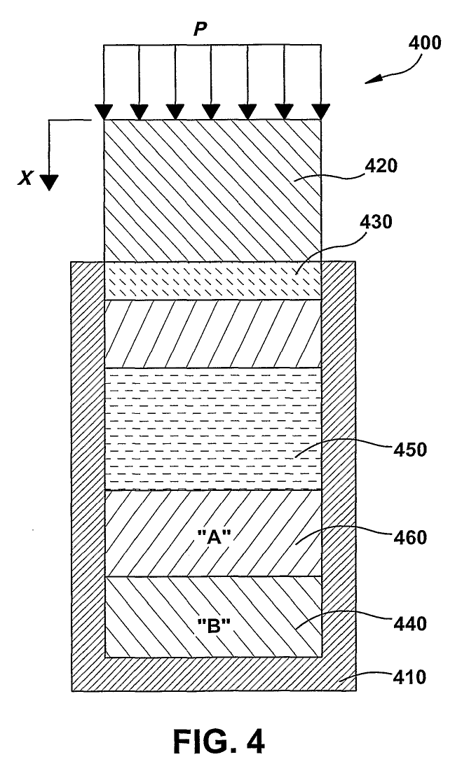

A mechanoelectric device in accordance with another embodiment of the present invention is illustrated in FIG. 4. This embodiment generates power as a cyclic external load is applied. Device 400 comprises a cylinder 410 that receives a piston 420, which seals to the cylinder 410 through an O-ring 430. Cylinder 410 contains an electrolyte solution 450, within which is immersed an optional porous electrode 440 and a hydrophobic nanoporous filter 460. When pressure is applied to piston 420, the smaller ions are forced into the nanoporous filter while larger ions are comparatively excluded. Thus, a potential forms, which can be harvested to do useful work. As the compressive load is removed, the liquid is expelled from the nanoporous filter due to surface tension. Thus, device 400 can operate under cyclic compression.

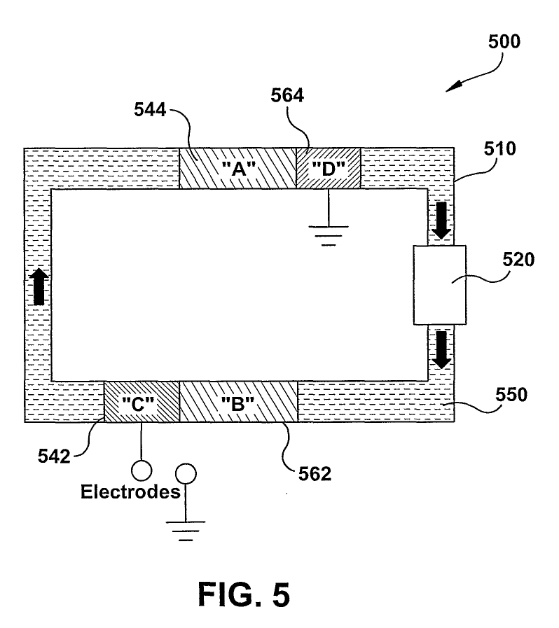

FIG. 5 depicts yet another alternative mechanoelectric embodiment formed in accordance with the present invention. In this embodiment, device 500 comprises a loading means 520 for applying a load, a liquid electrolyte 550, a first nanoporous filter 562, a second nanoporous filter 564, a first conductive porous block 542, a second conductive porous block 544, and a containment means 510 for containing the liquid electrolyte, the nanoporous filters and the porous conductive blocks. In this embodiment, liquid electrolyte 550 flows continuously through containment means 510 due to pressure provided by the loading means. When electrolyte 550 is forced into nanoporous filters 562 and 564, a portion of the smaller ions can pass through filters 562 and 564, while larger ions are comparatively excluded. Thus, device 500 develops and/or produces an electrical potential which can be harvested by porous conductive blocks 542 and 544. It should be noted that the number of pairs of porous conductive blocks and nanoporous filters is not limited to just two. Rather, any number of porous conductive blocks and nanoporous filters can independently be used in a device formed in accordance with the embodiment of FIG. 5.

Furthermore, the containment means of the device of FIG. 5 can include any of a variety of appropriate elements including tubing and/or pipes comprising any appropriate material. The loading means of the device of FIG. 5 can include any of a wide variety of pressure forming elements including, without limitation, pumps such as gear pumps, syringe pumps, and the like.

The thermoelectric embodiments of the present invention operate, in part, on the principle that when two dissimilar materials are in electrical contact charge moves across the interface (or the double layer) due to thermal motion. Furthermore, charge mobility changes as a function of temperature. Thus, when two dissimilar materials are in electrical contact a net potential difference is generated. Due to the small contact area of prior art systems, the efficiency of electric energy generation is quite low. However, in accordance with the present invention, a nanoporous solid in electrical contact with a liquid electrolyte is capable of very efficient energy conversion due to the large surface area present.

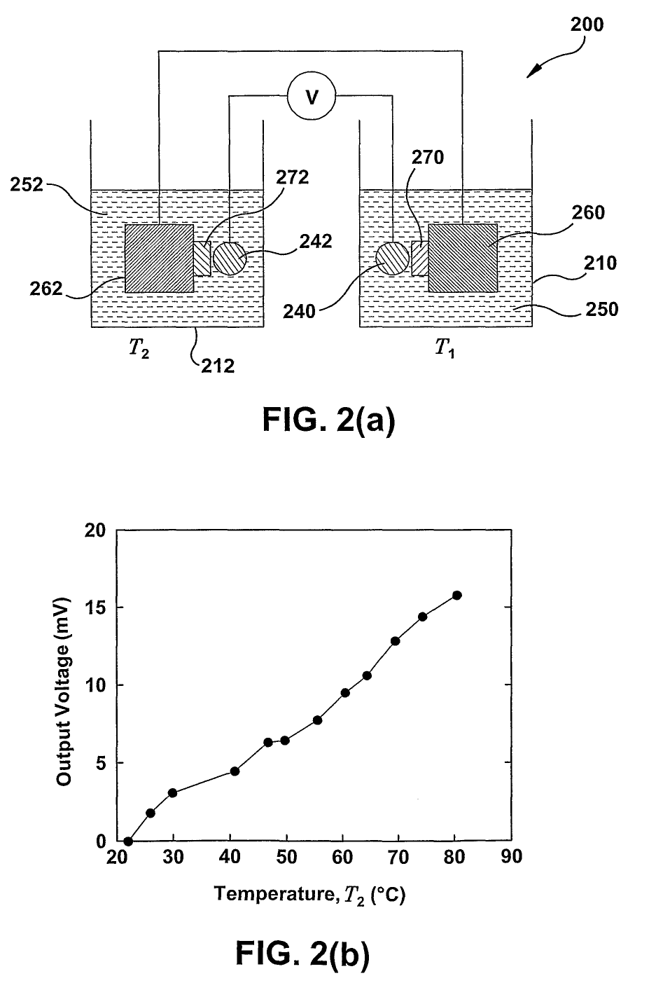

FIG. 2(a) illustrates one thermoelectric embodiment of the present invention. As is shown in FIG. 2(a), device 200 comprises two containment means 210 and 212, two porous electrodes 260 and 262, two counter electrodes 240 and 242, two insulation layers 270 and 272, and two electrolyte solutions 250 and 252. Containment means 210 and 212 receive the electrolyte solutions 250 and 252, respectively, within which are immersed, respectively, nanoporous electrodes 260 and 262, and counter electrodes 240 and 242. Nanoporous electrodes 260 and 262, and counter electrodes 240 and 242 are respectively separated by insulation layers 270 and 272. The counter electrodes can be connected by a voltage measuring device for measuring output voltage. When the two containment means are held at two different temperatures, a potential develops between them, which is due to the fact that ion mobility is a function of temperature. A representative voltage curve is shown in FIG. 2(b). The graph of FIG. 2(b) depicts the increase in output voltage as T₁ is held constant and T₂ is increased.

In one example, the device of FIG. 2(a) comprises two essentially identical nanoporous metal-liquid systems. Each system is formed by immersing a nanoporous Monel rod (OD: 0.3750 inch; length: 0.75 inch; micron grade: 0.5; provided by Chand Eisenmann Metallurgical, Inc.) in a 20 weight percent sodium chloride solution. The average pore size of the rods is about 500 nm. The two Monel rods are connected by a copper wire, and the potential difference between the two solutions is measured by a National Instruments 6936E Data Acquisition card in communication with a Dell Latitude D600 computer. The copper electrodes are separated from the nanoporous Monel rods by a thin insulation layer of Sterlitech PTU0247100 PTFE un-laminated membrane filter having a pore size of about 200 nm. The temperature (T₁) of one of the systems is maintained at room temperature (e.g., about 22° C.), while the temperature (T₂) of the other is increased using an Aldrich Z51 317-2 controlled-temperature bath. As can be seen from the results in FIG. 2(b), a portion of the thermal energy is converted to electric energy.

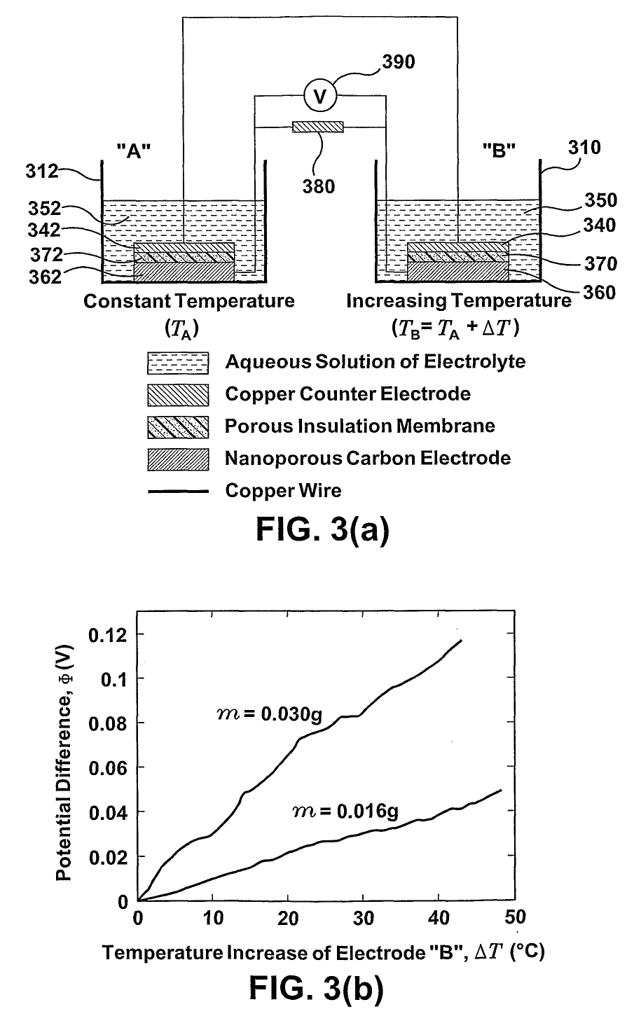

FIG. 3(a) depicts another thermoelectric embodiment in accordance with the present invention. As can be seen from FIG. 3(a), the device illustrated therein comprises two containment means 310 and 312, which respectively receive electrolytes 350 and 352. Containers 310 and 312 also hold, respectively, counter electrodes 340 and 342, and nanoporous electrodes 360 and 362. Counter electrodes 340 and 342 and nanoporous electrodes 360 and 362 are respectively, separated from one another by porous insulation membranes 370 and 372. Nanoporous electrodes 360 and 362, counter electrodes 340 and 342, and porous insulation membranes 370 and 372 are all immersed, respectively, in the electrolytes 350 and 352. In some variations of this embodiment, the carbon electrodes are electrically connected through a resistor and/or voltmeter. The cell generates electricity when the containment means are held at differing temperatures. A representative potential difference curve is shown in FIG. 3(b), which graphically illustrates that output increase as a function of temperature difference.

Although not restricted thereto, the foregoing example includes the following. A J. K. Baker Norit SX2 nanoporous carbon is used to create large-surface-area electrodes. The as-received carbon material is in powder form, with an average particle size of about 20 μm. The average pore size is about 1 to about 10 nm, and the specific surface area is about 800 m²/g. Nanoporous electrodes are prepared by mixing eight parts nanoporous carbon, one part Soltex ACE acetylene black (AB), and one part Aldrich 182702 polyvinylidene fluoride (PVF). The mixture is then placed in a steel mold and compressed using a type-5569 Instron machine at about 500 MPa for about five minutes at room temperature. This process forms disks having diameters of about 19.0 mm. The masses of the disks are in the range of about 15 to about 60 mg. A thermoelectric system is produced by immersing two substantially identical sandwich cells in a solution of about 30 weight percent sodium chloride, which is placed into two glass containers. The sandwich cells each comprise a copper counter electrode, a porous insulating membrane separator (Sterlitech PTU0247100 PTFE un-laminated membrane filter with the pore size of 200 nm), and a nanoporous carbon electrode.

In this example, the two copper counter electrodes are directly connected by a copper wire, and the two nanoporous carbon electrodes are connected by a copper wire through a 10 kΩ resistor, R₀. One container (A) is maintained at room temperature, T_{A}. The other (B) is heated using an Aldrich Z28 controlled-temperature bath, with the temperature increase rate lower than about 0.5° C./min. The voltage, Φ, across the resistor is measured with a NI 6036E DAQ board hosted by a computer with Labview. FIG. 3(b) shows two typical Φ-ΔT curves, with ΔT being the temperature increase of electrode B relative to A. It can be seen clearly that as the temperature difference increases, thermal energy is converted to electrical energy.

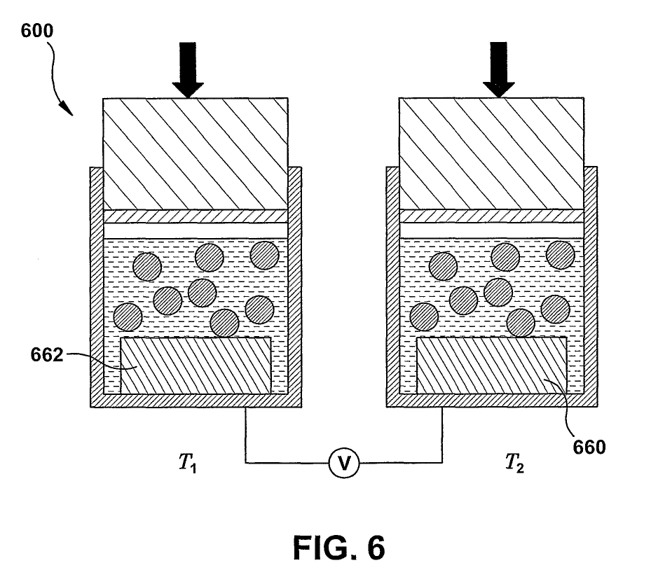

Still another alternative thermoelectric embodiment in accordance with the present invention is shown in FIG. 6. As can be seen in FIG. 6, device 600 comprises two piston assemblies similar to that of FIG. 1. The assemblies are held at different temperatures, which results in the thermoelectric power generation described above. Since ion infiltration is temperature dependent, the net output voltage of the two assemblies is different under the same external loading. Thus, a potential difference develops, which can be harvested through porous electrodes 660 and 662.

Alternatively, the foregoing embodiment can operate in electromechanical mode. According to this variation, the potential difference is manipulated to control the internal pressure of the two assemblies. Thus, by applying a potential, the system can output mechanical work.

In one embodiment, the present invention includes a high repeatability and reliability, simplicity in fabrication. In another embodiment, the present invention includes compatibility with small-scale devices, such as micro-electromechanical systems (MEMS), and with large-scale facilities such as electro-hydraulic systems. In still another embodiment, the present invention can be used to harvest electrical energy from ambient heat and mechanical motions, and/or to control temperatures, and/or to actively damp mechanical vibrations, and the like. In yet another embodiment, the present invention can also be a nanometer-scale power supply.

A thermoelectric system in accordance with the presenting invention is not required to contain a liquid phase. For instance, in embodiments where the liquid is a liquid metal, the temperature can be reduced, thereby solidifying the metal. In this embodiment the metal can still be conductive. Thus, such a system can still operate in thermoelectric mode because charge can still move across the interface of the confined phase (i.e., the solidified metal) and the nanoporous material in a temperature dependent manner.

In some embodiments the same nanoporous material can be used in either a mechanoelectric or thermoelectric system. Furthermore, some mechnoelectric embodiments can function in thermoelectric mode, and vice versa. For instance, as shown in FIG. 6 when a temperature gradient or fluctuation occurs in a mechanoelectric embodiment, the device also converts thermal energy to electrical energy. Thus, such an embodiment comprises a hybrid mechano/thermoelectric energy conversion device.

Although the invention has been described in detail with particular reference to certain embodiments detailed herein, other embodiments can achieve the same results. Variations and modifications of the present invention will be obvious to those skilled in the art and the present invention is intended to cover in the appended claims all such modifications and equivalents.

What is claimed is:

1. A mechanoelectric power generating device comprising:
a nanoporous material disposed within a containment means, wherein the nanoporous material is capable of separating ions according to size;
an electrolyte containing anions and cations disposed within the containment means, wherein the electrolyte is made up of anions and cations that differ in size so that the smaller ion is capable of permeating the nanoporous material, and wherein the larger ions are substantially excluded from the nanoporous material, and wherein the electrolyte is capable of being contained within the containment means;
a loading means located and/or disposed within the containment means, wherein the loading means is capable of imparting a mechanical load upon the contents of the containment means, the load being sufficient to cause at least a portion of the electrolyte to at least partially infiltrate the nanoporous material; and
at least one contact in electrical communication with the containment means, the electrolyte and/or the nanoporous material, wherein the contact is capable of harvesting any excess electrical charge.

2. The mechanoelectric device of claim 1, further comprising a high-surface area electrode capable of harvesting excess electrical charge.

3. The mechanoelectric device of claim 2, wherein the high-surface area electrode is selected from one or more of porous metal, porous alloy, porous carbon, nanoclusters, stacks of nanoparticles, nanolayers, nanodots, nanowires, nanofibers, and nanorods.

4. The mechanoelectric device of claim 2, wherein the high-surface area electrode comprises porous Monel.

5. The mechanoelectric device of claim 1, wherein the electrolyte is selected from one or more of sodium chloride, sodium iodide, potassium chloride, and potassium iodide.

6. The mechanoelectric device of claim 1, wherein the nanoporous material is selected from one or more of metal oxides, silicon, carbon, zeolites, silicalites, porous polymers, porous metals and alloys, diatoms, radiolarii, and abalone shell, and natural clays.

7. The mechanoelectric device of claim 6, wherein the nanoporous metal oxide is selected from one or more of silica, titania, alumina, zirconia, magnesia, Nb₂O₅, SnO₂, In₂O₃, and ZnO.

8. The mechanoelectric device of claim 6, wherein the nanoporous natural clay is selected from one or more of kaolins, serpentines, smectites, glauconite, chlorites, vermiculites, attapulgite, sepiolite, allophane, imogolite, zeolites, and silicalite.

9. The mechanoelectric device of claim 6, wherein the nanoporous polymer is selected from one or more of silicone, latex, polyolefins, polypyrrole, polyurethanes, and acetates.

10. The mechanoelectric device of claim 6, wherein the nanoporous carbon is selected from one or more of amorphous carbon, semi-crystalline carbon, crystalline carbon, carbon nanotubes, and graphene layers.

11. The mechanoelectric device of claim 6, wherein the nanoporous metal or alloy is selected from iron, steel, gold, silver, and copper.

12. A thermoelectric power generating device comprising:
a conductive means that is capable of conducting charge to and from a nanoporous material, wherein the conductive means is disposed in a containment means;
a nanoporous material disposed within the containment means, wherein the nanoporous material is capable of separating charge and/or containing excess charge, wherein the nanoporous material and the conductive means are in thermal and electrical communication with the containment means;
a temperature control means designed to permit control of the temperature of the containment means, the conductive means, and the nanoporous material; and
a means for harvesting excess charge from the conductive means and/or containment means.

13. The thermoelectric power generating device of claim 12, wherein the containment means is capable of receiving a loading means.

14. The thermoelectric power generating device of claim 13, further comprising a loading means.

15. The thermoelectric power generating device of claim 12, wherein the nanoporous material is selected from one or more of metal oxides, silicon, carbon, zeolites, silicalites, porous polymers, porous metals and alloys, diatoms, radiolarii, and abalone shell, and natural clays.

16. The thermoelectric power generating device of claim 15, wherein the nanoporous metal oxide is selected from one or more of silica, titania, alumina, zirconia, magnesia, Nb₂O₅, SnO₂, In₂O₃, and ZnO.

17. The thermoelectric power generating device of claim 15, wherein the nanoporous natural clay is selected from one or more of kaolins, serpentines, smectites, glauconite, chlorites, vermiculites, attapulgite, sepiolite, allophane, imogolite, zeolites, and silicalite.

18. The thermoelectric power generating device of claim 15, wherein the nanoporous polymer is selected from one or more of silicone, latex, polyolefins, polypyrrole, polyurethanes, and acetates.

19. The thermoelectric power generating device of claim 15, wherein the nanoporous carbon is selected from one or more of amorphous carbon, semi-crystalline carbon, crystalline carbon, carbon nanotubes, graphene layers, nanoclusters, stacks of nanoparticles, nanolayers, nanodots, nanowires, nanofibers, and nanorods.

20. The thermoelectric power generating device of claim 15, wherein the nanoporous metal or alloy is selected from iron, steel, gold, silver, copper, nanoclusters, stacks of nanoparticles, nanolayers, nanodots, nanowires, nanofibers, and nanorods.
